(19) United States
(12) Patent Application Publication
(10) Pub. No.: US 2026/0143839 A1
(43) Pub. Date: May 21, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Liming PENG, Wuhan, Hubei (CN); Dewei SONG, Wuhan, Hubei (CN); Fei AI, Wuhan, Hubei (CN); Can HUANG, Wuhan, Hubei (CN); Rui HE, Wuhan, Hubei (CN); Chuan SHUAI, Wuhan, Hubei (CN)

(21) Appl. No.: 18/995,632

(22) PCT Filed: Dec. 3, 2024
(86) PCT No.: PCT/CN2024/136370

§ 371 Date: Jan. 16, 2025

(30) Foreign Application Priority Data
Nov. 19, 2024 (CN) 202411655329.1

(51) Int. Cl. H10F 39/00

(52) U.S. Cl. CPC H10F 39/8057

(57) ABSTRACT

The present disclosure provides a display panel and a display device. The display panel includes a substrate, a first metal layer, a photosensitive unit, and a second metal layer. The first metal layer is disposed on the substrate. The first metal layer includes a first light-shielding part. By connecting the first light-shielding part to a constant voltage source, a potential of the first light-shielding part is ensured to be always in a stable state, preventing the potential of the first light-shielding part from floating, and then avoiding an electrical noise problem caused by a floating potential of the first light-shielding part.

This application claims priority to Chinese Patent Application No. 202411655329.1 filed on Nov. 19, 2024, the entire contents of which are incorporated in the present disclosure by reference.

### TECHNICAL FIELD

The present disclosure relates to the field of display technologies, and in particular, to a display panel and a display device.

### BACKGROUND

With a rapid development of the panel display industry, a market demand for highly functional and highly integrated display panels is increasing. Currently, ambient light and color temperature sensing functions are generally implemented through external sensors, and a use of such external sensors requires additional installation space, resulting in wider frame of the display panels.

A photoelectric sensor can integrate functions of an ambient light sensor and a color temperature sensor, and has advantages of fast response, simple structure, and high accuracy. The photocurrent sensor can be directly integrated inside a display panel or device, thus effectively saving space.

### SUMMARY

Embodiments of the present disclosure provide a display panel and a display device to alleviate deficiencies in related arts.

In order to realize the above functions, technical proposals provided by embodiments of the present disclosure are as the following.

In a first aspect, embodiments of the present disclosure provide a display panel, including:
a substrate;
a first metal layer disposed on the substrate and including a first light-shielding part; and
a photosensitive unit disposed on one side of the first light-shielding part away from the substrate, where the photosensitive unit includes a photosensitive doping part, a photosensitive part, and a photosensitive electrode disposed in a stacked manner, one end of the photosensitive part is connected to the photosensitive doping part, and another end of the photosensitive part is connected to the photosensitive electrode; and
where an orthographic projection of the first light-shielding part on the substrate covers an orthographic projection of the photosensitive part on the substrate, and the first light-shielding part is connected to a constant voltage source.

In a second aspect, embodiments of the present disclosure provide a display device. The display device includes a display panel, and the display panel includes:
a substrate;
a first metal layer disposed on the substrate and including a first light-shielding part; and
a photosensitive unit disposed on one side of the first light-shielding part away from the substrate, where the photosensitive unit includes a photosensitive doping part, a photosensitive part, and a photosensitive electrode disposed in a stacked manner, one end of the photosensitive part is connected to the photosensitive doping part, and another end of the photosensitive part is connected to the photosensitive electrode; and
where an orthographic projection of the first light-shielding part on the substrate covers an orthographic projection of the photosensitive part on the substrate, and the first light-shielding part is connected to a constant voltage source.

### DESCRIPTION OF DRAWINGS

Technical proposals and other beneficial effects of the present disclosure will become apparent through a detailed description of specific embodiments of the present disclosure below in conjunction with the accompanying drawings.

FIG. 1 is a schematic structural diagram of a display panel provided by embodiments of the present disclosure;

FIG. 2 is a schematic cross-sectional view corresponding to A-A′ in FIG. 1 provided by embodiments of the present disclosure;

FIG. 3 is an enlarged schematic view of a corresponding area B in FIG. 1 according to embodiments of the present disclosure;

FIG. 4 is an enlarged schematic diagram of a corresponding fan-out area in FIG. 3 provided by embodiments of the present disclosure;

FIG. 5 is a schematic cross-sectional diagram corresponding to C-C′ in FIG. 4 provided by embodiments of the present disclosure;

FIG. 6A to FIG. 6I are schematic diagrams corresponding to each step of a manufacturing method of a display panel provided by embodiments of the present disclosure; and

FIG. 7 is a schematic structural diagram of a display device provided by embodiments of the present disclosure.

### EMBODIMENTS OF THE INVENTION

Technical proposals in embodiments of the present disclosure will be clearly and completely described below with reference to the accompanying drawings in the embodiments of the present disclosure. Obviously, the described embodiments are only some of the embodiments of the present disclosure, rather than all of the embodiments. Based on the embodiments in the present disclosure, all other embodiments obtained by those skilled in the art without making creative efforts fall within a scope of protection of the present disclosure. In addition, it should be understood that specific embodiments described here are only used to illustrate and explain the present disclosure, and are not used to limit the present disclosure. In the present disclosure, unless otherwise stated, orientational terms used such as “upper” and “lower” generally refer to the upper and lower orientations of the device in actual use or working mode, specifically the orientations of the drawings. The terms “inside” and “outside” refer to the outline of the device.

In addition, the terms “first” and “second” are used for descriptive purposes only, and features defined with “first” and “second” may explicitly or implicitly include one or more of the described features. In the description of the present disclosure, “plurality” means two or more than two, unless otherwise explicitly and specifically limited.

In the description of the present disclosure, it should be noted that, unless otherwise clearly stated and limited, the terms “install”, “connected”, and “connecting” should be understood in a broad sense. For example, it may be a fixed connection or a detachable connection; it may be a mechanical connection, an electrical connection, or mutual communication; it may be a direct connection or an indirect connection through an intermediary; it may be an internal connection between two elements or an interaction between two elements. For those of ordinary skill in the art, specific meanings of the above terms in the present disclosure can be understood according to specific conditions.

The following disclosure provides many different embodiments for implementing various structures of the present disclosure. To simplify the disclosure of the present disclosure, components and arrangements of specific examples are described below. Of course, they are merely examples and are not intended to limit the present disclosure. In addition, the present disclosure provides examples of various specific processes and materials, but one of ordinary skill in the art can recognize the present disclosure of other processes and/or the use of other materials.

Embodiments of the present disclosure provide a display panel and a display device. Each is explained in detail below. It should be noted that the order of description of the following embodiments does not limit the preferred order of the embodiments.

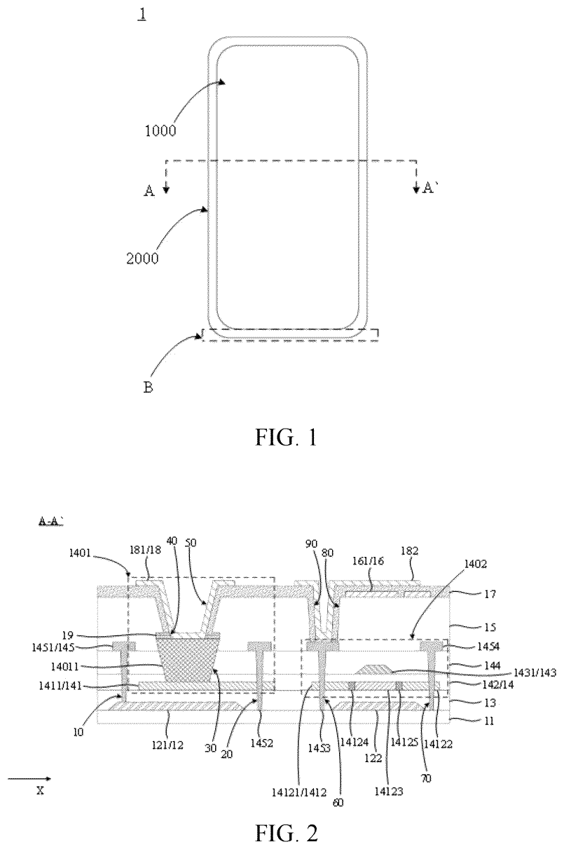

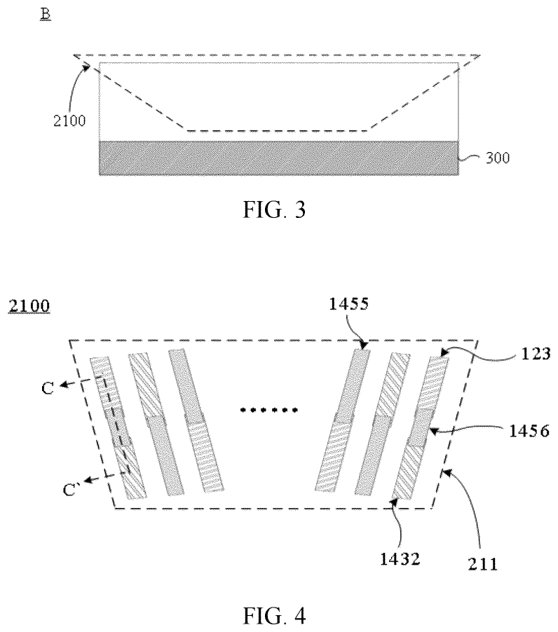

Please refer to FIG. 1 and FIG. 2. FIG. 1 is a schematic structural diagram of a display panel provided by embodiments of the present disclosure, and FIG. 2 is a schematic cross-sectional view corresponding to A-A′ in FIG. 1 provided by embodiments of the present disclosure.

In one embodiment, the display panel 1 includes but is not limited to a liquid crystal display panel. The display panel 1 includes a substrate 11, a first metal layer 12, a buffer layer 13, a thin film transistor layer 14, a planarization layer 15, a second transparent electrode layer 16, a passivation layer 17, and a first transparent electrode layer 18.

The substrate 11 may include a rigid substrate or a flexible substrate. If the substrate 11 is a rigid substrate, the material thereof may be metal or glass. If the substrate 11 is a flexible substrate, the material thereof may include at least one of acrylic resin, methacrylate resin, polyisoprene, vinyl resin, epoxy resin, polyurethane resin, cellulose resin, siloxane resin, polyimide resin, and polyamide resin. The embodiments do not restrict this specifically.

The first metal layer 12 is disposed on one side of the substrate 11. The material of the first metal layer 12 includes but is not limited to molybdenum (Mo), molybdenum-aluminum (MoAl) laminate, or molybdenum-aluminum-molybdenum (MoAlMo) laminate, thereby reducing A sheet resistance (Rs) of the first metal layer 12 and helping to improve a performance and signal transmission efficiency of the display panel 1.

The buffer layer 13 is provided on one side of the first metal layer 12 away from the substrate 11. The buffer layer 13 can play a buffering role. The material of the buffer layer 13 includes but is not limited to silicon nitride (SiNx), silicon oxide (SiOx), or silicon oxynitride (SiONx), or a combination of film layers of the above.

The thin film transistor layer 14 includes a semiconductor layer 141, a gate insulation layer 142, a third metal layer 143, an interlayer insulation layer 144, and a second metal layer 145 which are stacked on the substrate 11. The thin film transistor layer 14 includes a photosensitive unit 1401 and a control unit 1402. The control unit 1402 is connected to the photosensitive unit 1401. The control unit 1402 can control turn-on, turn-off, and other states of the photosensitive unit 1401.

The semiconductor layer 141 is provided on one side of the buffer layer 13 away from the first metal layer 12. The semiconductor layer 141 includes a photosensitive doping part 1411 and a semiconductor part 1412 that are spaced apart. The semiconductor part 1412 includes a first doped portion 14121, a second doped portion 14122, and a channel portion 14123 located between the first doped portion 14121 and the second doped portion 14122. The material of the channel portion 14123 may be polycrystalline silicon (poly-Si) formed by converting amorphous silicon (a-Si) using an excimer laser annealing (ELA) process. A doping concentration of the first doped portion 14121 and a doping concentration of the second doped portion 14122 are the same. Both the first doped portion 14121 and the second doped portion 14122 can be formed by heavy doping of phosphorus ions using polysilicon.

The gate insulation layer 142 is provided on one side of the semiconductor layer 141 away from the buffer layer 13. The gate insulation layer 142 can be configured to prevent a short circuit caused by a contact between the semiconductor layer 141 and the third metal layer 143. The material of the gate insulation layer 142 includes but is not limited to silicon oxide, silicon nitride, aluminum oxide, or a combination of the above.

The third metal layer 143 is disposed on one side of the gate insulation layer 142 away from the semiconductor layer 141. The third metal layer 143 includes a gate 1431 corresponding to the channel portion 14123. An orthographic projection of the gate 1431 on the substrate 11 covers an orthographic projection of the channel portion 14123 on the substrate 11. The material of the third metal layer 143 includes but is not limited to at least one of molybdenum (Mo), aluminum (Al), platinum (Pt), palladium (Pd), silver (Ag), magnesium (Mg), gold (Au), at least one metal among nickel (Ni), neodymium (Nd), iridium (Ir), chromium (Cr), calcium (Ca), titanium (Ti), tantalum (Ta), and tungsten (W).

The interlayer insulation layer 144 is disposed on one side of the third metal layer 143 away from the gate insulation layer 142. The material of the interlayer insulation layer 144 includes, but is not limited to, silicon nitride (SiNx), silicon oxide (SiOx), or silicon oxynitride (SiONx), or a combination of film layers of the above.

The second metal layer 145 is disposed on one side of the interlayer insulation layer 144 away from the third metal layer 143. The material of the second metal layer 145 includes, but is not limited to, at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), and tungsten (W). The second metal layer 145 includes a first electrode 1451, a second electrode 1452, a third electrode 1453, and a fourth electrode 1454. The third electrode 1453 is connected to the first doped portion 14121, and the fourth electrode 1454 is connected to the second doped portion 14122.

The planarization layer 15, the second transparent electrode layer 16, the passivation layer 17, and the first transparent electrode layer 18 are sequentially stacked on one side of the second metal layer 145 away from the interlayer insulation layer 144. The material of the passivation layer 17 includes, but is not limited to, silicon nitride (SiNx), silicon dioxide (SiOx), or silicon oxynitride (SiONx), or a combination of film layers of the above. The first transparent electrode layer 18 includes a photosensitive electrode 181 and a pixel electrode 182. The second transparent electrode layer 16 includes a common electrode 161. The material of the first transparent electrode layer 18 and the material of the second transparent electrode layer 16 include but are not limited to metal oxide materials. The metal oxide materials are preferably indium tin oxide (ITO) with high visible light transmittance and good conductivity.

The photosensitive unit 1401 may be a photosensitive sensor, which may be used for environmental photocurrent detection. The photosensitive unit 1401 includes the photosensitive doping part 1411, the photosensitive part 14011, and the photosensitive electrode 181 which are stacked. One end of the photosensitive part 14011 is connected to the photosensitive doping part 1411, and another end of the photosensitive part 14011 is connected to the photosensitive electrode 181. The material of the photosensitive part 14011 includes but is not limited to amorphous silicon (a-Si). When external light irradiates the photosensitive part 14011, a photocurrent can be generated between the photosensitive doping part 1411 and the photosensitive electrode 181.

Specifically, the photosensitive unit 1401 may be a PIN structure. Specifically, the photosensitive unit 1401 includes an N-type layer, an I-type layer disposed on the N-type layer, and a P-type layer disposed on the I-type layer.

The photosensitive doping part can be used as an N-type layer, and the material of the photosensitive doping part is N-type doped polysilicon, which provides carrier electrons and helps to form an electric field. The photosensitive part 14011 can be used as an I-type layer, and the material of the photosensitive part 14011 may be amorphous silicon. The amorphous silicon is an intrinsic semiconductor and has good light absorption ability. Under illumination, the photosensitive part 14011 can absorb photons and generate electron-hole pairs. The photosensitive electrode 181 can be used as a P-type layer, and the material of the photosensitive electrode 181 may be indium tin oxide (ITO). The photosensitive electrode 181 can provide holes to help to establish a built-in electric field. Light can enter the photosensitive part 14011 through the photosensitive electrode 181, thereby realizing a photoelectric effect.

It can be understood that this embodiment integrates photosensitive elements into an interior of the display panel 1 to achieve under-screen color temperature sensing and self-adjustment functions. Compared with solutions of external photosensitive elements in related arts, this embodiment has effects of higher degree of integration and lower costs, and saves structural space.

Please continue referring to FIG. 1 and FIG. 2. In one embodiment, the first metal layer 12 includes a first light-shielding part 121. The first light-shielding part 121 is provided corresponding to the photosensitive unit 1401. An orthographic projection of the photosensitive part 14011 on the substrate 11 is located within an orthographic projection of the first light-shielding part 121 on the substrate 11, so that unnecessary light is avoided from irradiating the photosensitive unit 1401, reducing an impact of light interference on the photosensitive part 14011, thereby improving an accuracy and stability of a photoelectric signal.

Specifically, the first light-shielding part 121 is connected to a constant voltage source. It should be noted that the photosensitive unit 1401 can integrate functions of an ambient light sensor and a color temperature sensor, and has advantages of fast response speed, simple structure, and high precision, but during actual operation, a floating metal inside the display panel 1 may interfere with a reading of the photosensitive unit 1401, decreasing a measurement accuracy of this sensor.

It can be understood that in this embodiment, by directly connecting the first light-shielding part 121 to the constant voltage source, it is possible to ensure that a potential of the first light-shielding part 121 is always in a stable state. The constant voltage source provides a fixed voltage to ensure that the first light-shielding part 121 is not interfered by external signals during operation, and the potential of the first light-shielding part 121 does not float. Therefore, the potential of the first light-shielding part 121 can be effectively prevented from drifting or changing (i.e., floating). Since the light interference is effectively controlled, the photosensitive unit 1401 can sense a light signal more accurately and convert it into an electrical signal, thereby improving an efficiency and stability of the photosensitive unit 1401.

Please continue referring to FIG. 1 and FIG. 2. In one embodiment, the first electrode 1451 is connected to the first light-shielding part 121. One end of the second electrode 1452 is connected to the photosensitive doping part 1411, and another end of the second electrode 1452 is connected to the control unit 1402.

Specifically, the first electrode 1451 is connected to the first light-shielding part 121 and applies a constant voltage (such as a COM signal), so that the first light-shielding part 121 can maintain a constant voltage state, which can effectively avoid an electrical noise problem caused by a floating potential of the first light-shielding part 121, thus reducing an interference to the photosensitive unit 1401 and helping to improve the accuracy and stability of the photoelectric signal.

At the same time, by connecting the photosensitive doping part 1411 to the second electrode 1452, and by connecting the second electrode 1452 to the control unit 1402, a more precise current flow path can be achieved and the accuracy of the photoelectric signal can be improved. A connection between the photodoped portion 1411 and the control unit 1402 helps to maintain a stable photocurrent output, ensuring that the photosensitive unit 1401 can correctly detect and respond to changes in external light without affecting the measurement accuracy due to unnecessary potential interference.

It should be noted that the technical proposal proposed in this embodiment is suitable for application scenarios in which the display panel 1 integrates photoelectric sensing. In order to better illustrate an innovation of this embodiment, this embodiment takes the constant voltage of a COM signal as an example to illustrate the technical proposal of this embodiment.

Please continue referring to FIG. 1 and FIG. 2. In one embodiment, the control unit 1402 is connected to the photosensitive unit 1401, and the control unit 1402 can control the turn-on, turn-off, and other states of the photosensitive unit 1401. The control unit 1402 may be a thin film transistor structure, and the control unit 1402 includes the semiconductor part 1412, the gate insulation layer 142, the gate 1431, the interlayer insulation layer 144, the third electrode 1453, and the fourth electrode 1454. One end of the third electrode 1453 is connected to the first doped portion 14121, another end of the third electrode 1453 is connected to the second electrode 1452, and the fourth electrode 1454 is connected to the second doped portion 14122.

It should be noted that one of the third electrode 1453 and the fourth electrode 1454 may be a source, and the other one of the third electrode 1453 and the fourth electrode 1454 may be a drain. Specific positions of the source and the drain can be selected according to design requirements, so that this embodiment has a high degree of flexibility.

Furthermore, the third electrode 1453 can be connected to the pixel electrode 182, and the control unit 1402 can control current and voltage changes of the pixel electrode 182 by adjusting currents of the source and the drain, thus affecting a display effect.

The first metal layer 12 further includes a second light-shielding part 122. The second light-shielding part 122 is spaced apart from the first light-shielding part 121. The second light-shielding part 122 is disposed corresponding to the control unit 1402. An orthographic projection of the semiconductor part 1412 on the substrate 11 is located within an orthographic projection of the second light-shielding part 122 on the substrate 11. The second light-shielding part 122 is configured to prevent light from irradiating the semiconductor part 1412, thereby preventing the device performance of the semiconductor part 1412 from being affected.

It can be understood that in this embodiment, the first metal layer 12 includes the first light-shielding part 121 and the second light-shielding part 122, the semiconductor layer 141 includes the photosensitive doping part 1411 and the semiconductor part 1412 arranged apart from each other, and the second metal layer 145 includes the first electrode 1451, the second electrode 1452, the third electrode 1453, and the fourth electrode 1454, so that a process difficulty of the display panel 1 is reduced, thereby saving manufacturing costs and improving production efficiency and yield.

At the same time, a structural design of the display panel 1 provided in this embodiment simplifies a hierarchical relationship. By integrating the photosensitive unit 1401 and the control unit 1402 in the same thin film transistor layer 14, and by directly integrating the photosensitive unit 1401 in a structure of the display panel 1, the photosensitive unit 1401 can directly respond to external light without a need for additional photosensitive elements, thereby reducing a need for external photosensitive elements, which is conducive to an integration of the device and saves space.

Please continue referring to FIG. 1 and FIG. 2. In one embodiment, the semiconductor part 1412 further includes a third doped portion 14124 and a fourth doped portion 14125. The third doped portion 14124 is disposed between the channel portion 14123 and the first doped portion 14121. The fourth doped portion 14125 is provided between the channel portion 14123 and the second doped portion 14122. The doping concentration of the first doped portion 14121 is the same with the doping concentration of the second doped portion 14122 are the same, a doping concentration of the third doped portion 14124 is the same with a doping concentration of the fourth doped portion 14125, and the doping concentration of the third doped portion 14124 is less than the doping concentration of the first doped portion 14121.

It can be understood that in this embodiment, by arranging the third doped portion 14124 and the fourth doped portion 14125 and making their doping concentrations less than the doping concentrations of the first doped portion 14121 and the second doped portion 14122, a gradient of the doping concentrations near the channel portion 14123 is reduced, which alleviates a mobility reduction problem caused by excessive doping concentration, thereby improving a current transmission efficiency and response speed.

Specifically, since the third doped portion 14124 is provided between the channel portion 14123 and the first doped portion 14121, and the fourth doped portion 14125 is provided between the channel portion 14123 and the second doped portion 14122, the third doped portion 14124 and the fourth doped portion 14125 can both serve as transition portions, helping to form a smooth current path, reducing current spikes in turn-on and turn-off states, and improving conduction characteristics of the control unit 1402 to avoid sudden changes in current.

At the same time, the first doped portion 14121 and the second doped portion 14122 have the same doping concentration, and the third doped portion 14124 and the fourth doped portion 14125 have the same doping concentration, so that a uniform distribution of current in the channel portion 14123 is ensured, the problem such as unbalanced current distribution due to uneven doping is avoided, and a performance consistency and stability of the semiconductor part 1412 is improved.

Please continue referring to FIG. 1 and FIG. 2. In one embodiment, the buffer layer 13 is disposed between the first metal layer 12 and the semiconductor layer 141. The gate insulation layer 142 is disposed between the semiconductor layer 141 and the third metal layer 143. The interlayer insulation layer 144 is disposed on one side of the third metal layer 143 away from the gate insulation layer 142. Therefore, it is possible to ensure that short circuits do not occur between different conductive parts, making signal transmission more stable, and thus improving an overall reliability and performance of the display panel 1.

The display panel 1 is provided with a first through hole 10 and a second through hole 20. The first electrode 1451 passes through the first through hole 10 to connect with the first light-shielding part 121. The first through hole 10 penetrates the interlayer insulation layer 144, the gate insulation layer 142, and at least part of the buffer layer 13. One end of the second electrode 145 2 passes through the second through hole 20 to connect with the photosensitive doping part 1411. The second through hole 20 penetrates the interlayer insulation layer 144, the gate insulation layer 142, the photosensitive doping part 1411, and the buffer layer 13. Another end of the second electrode 1452 is connected to the third electrode 1453.

Furthermore, the display panel 1 is also provided with a sixth through hole 60 and a seventh through hole 70. The third electrode 1453 passes through the sixth through hole 60 to connect with the first doped portion 14121. The sixth through hole 60 penetrates the interlayer insulation layer 144, the gate insulation layer 142, the first doped portion 14121, and the buffer layer 13. The fourth electrode 1454 passes through the seventh through hole 70 to connect with the second doped portion 14122. The seventh through hole 70 penetrates the interlayer insulation layer 144, the gate insulation layer 142, the second doped portion 14122, and the buffer layer 13.

It can be understood that arrangements can be adopted as follows:
arranging the second through hole 20 to penetrate the photosensitive doped part 1411, arranging the second electrode 1452 to pass through the photosensitive doped part 1411, arranging the photosensitive doped part 1411 to surround the second electrode 1452, arranging the sixth through hole 60 to penetrate the first doped portion 14121, arranging the third electrode 1453 to pass through the first doped portion 14121, arranging the first doped portion 14121 to surround the third electrode 1453, arranging the seventh through hole 70 to penetrate the first doped portion 14121, arranging the fourth electrode 1454 to pass through the second doped portion 14122, and arranging the second doped portion 14122 to surround the fourth electrode 1454. With the above arrangements, isolations between these electrodes is optimized, thereby preventing unnecessary electrical interference or short circuit between the electrodes, and improving stability of the electrodes.

At the same time, it can also enhance the stability of the electrical connection between the electrodes and the doped portions, increase contact areas between the electrodes and the doped portions, and avoid unstable contact problems caused by local poor contact or mismatched electrode morphology.

Please continue referring to FIG. 1 and FIG. 2. In one embodiment, the orthographic projection of the second light-shielding part 122 on the substrate 11 covers the orthographic projection of the semiconductor part 1412 on the substrate 11, and the orthographic projection of the second light-shielding part 122 on the substrate 11 covers an orthographic projection of the third doped portion 14124 on the substrate 11 and an orthographic projection of the fourth doped portion 14125 on the substrate 11.

Specifically, the second light-shielding part 122 is disposed corresponding to a channel region and a lightly doped region. The second light-shielding part 122 has a semi-surrounding structure and only covers the channel portion 14123, the third doped portion 14124, and the fourth lightly doped portion to avoid an impact of light on these regions. It is understandable that the doping concentration of the third doped portion 14124 and the fourth lightly doped portion is low, which generally has a greater impact on current control and mobility during operation. Therefore, a design of the second light-shielding part 122 can enable that these areas are in a stable electrical state, thereby improving the stability and performance of the display panel 1.

At the same time, compared with a full light-shielding design (the light-shielding layer completely covers the semiconductor part 1412) in related arts, a semi-surrounding design can simplify a manufacturing process of the second light-shielding part 122, thereby improving a manufacturing efficiency, reducing costs, and ensuring that a light-shielding effect is not affected.

Please continue referring to FIG. 1 and FIG. 2. In one embodiment, the display panel 1 is further provided with a third through hole 30. At least part of the photosensitive part 14011 is filled in the third through hole 30, and the third through hole 30 penetrates the interlayer insulation layer 144 and at least part of the gate insulation layer 142. This avoids contact between the photosensitive part 14011 and other film layers, effectively improves electrical isolation, prevents possible electrical short circuits or leaks, and improves the electrical safety and reliability of the display panel 1.

The size of one side of the photosensitive part 14011 away from the substrate 11 is greater than the size of one side of the third through hole 30 away from the substrate 11. Specifically, the side of the photosensitive part 14011 away from the substrate 11 protrudes from one side surface of the interlayer insulation layer 144 away from the substrate 11, that is, a distance between a side surface of the photosensitive part 14011 away from the substrate 11 and the substrate 11 is greater than a distance between the side surface of the interlayer insulation layer 144 away from the substrate 11 and the substrate 11, thereby making a contact between the photosensitive part 14011 and the third through hole 30 more stable.

It should be noted that the sizes mentioned in this embodiment are a width of the photosensitive part 14011 in a first direction X and a width of the fifth through hole 50 in the first direction X, where the first direction is the direction X in FIG. 2.

Furthermore, the first through hole 10, the second through hole 20, the third through hole 30, the sixth through hole 60, and the seventh through hole 70 may be processed at one time through a photomask, which makes the manufacturing process simpler and can efficiently realize correct connections of the multiple electrodes, reducing a complexity of multiple processes. At the same time, it helps to maintain a production consistency of the display panel 1, reduce process steps, reduce a production complexity and costs, ensure performance and a stable structure, and improve a product qualification rate.

Please continue referring to FIG. 1 and FIG. 2. In one embodiment, the display panel 1 further includes a protective layer 19. The protective layer 19 is disposed on one side of the photosensitive part 14011 away from the photosensitive doping part 1411. The protective layer 19 is provided with a fourth through hole 40, and the fourth through hole 40 penetrates the protective layer 19. The planarization layer 15 is disposed on one side of the second metal layer 145 away from the interlayer insulation layer 144. The planarization layer 15 is provided with a fifth through hole 50, and the fifth through hole 50 penetrates at least part of the planarization layer 15. The fifth through hole 50 is communicated with the fourth through hole 40. The first transparent electrode layer 18 is disposed on one side of the planarization layer 15 away from the second metal layer 145. The first transparent electrode layer 18 includes the photosensitive electrode 181, and the photosensitive electrode 181 passes through the fourth through hole 40 and the fifth through hole 50 to connect with the photosensitive part 14011.

The material of the protective layer 19 includes but is not limited to silicon nitride (SiNx), silicon dioxide (SiOx), or silicon oxynitride (SiONx), or a combination of the above. The material of the planarization layer 15 includes but is not limited to organic photoresist materials. It can be understood that by providing the protective layer 19, the photosensitive part 14011 can be effectively prevented from being damaged by the external environment, and at the same time panel failures caused by pollution or electrical short circuits can be avoided. Setting the planarization layer 15 not only helps to improve an overall planarization of the panel, but also further optimizes a uniformity performance of subsequent layers, thereby improving the quality and consistency of the display panel 1.

At the same time, by arranging the fourth through hole 40 and the fifth through hole 50 and ensuring that the fifth through hole 50 is communicated with the fourth through hole 40, the photosensitive part 14011 and the photosensitive electrode 181 can be accurately connected, avoiding docking errors and ensuring stable electrical performance.

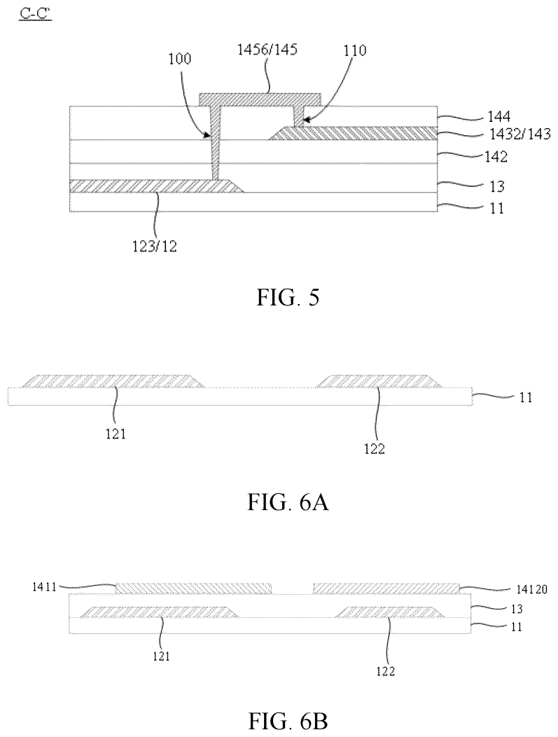

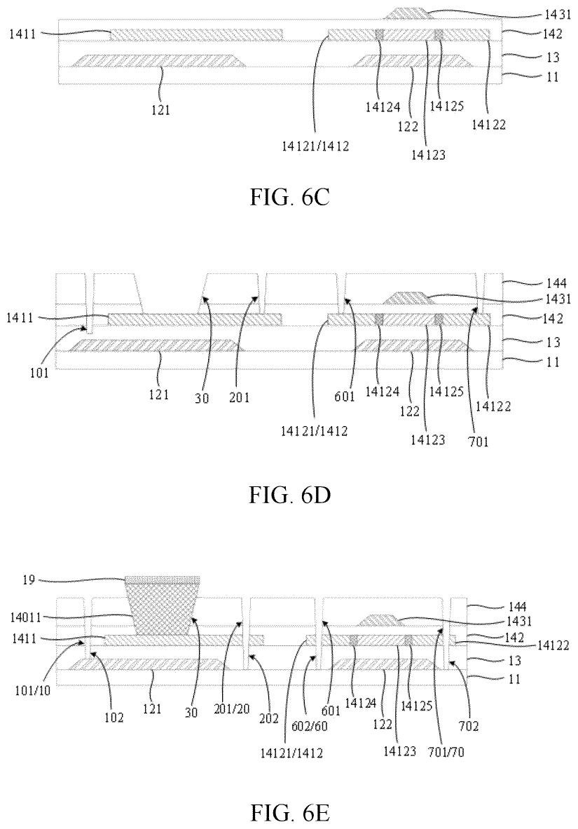

Please refer to FIG. 1, FIG. 2, FIG. 3, and FIG. 4. FIG. 3 is an enlarged schematic view of a corresponding area B in FIG. 1 according to embodiments of the present disclosure, and FIG. 4 is an enlarged schematic diagram of a corresponding fan-out area in FIG. 3 provided by embodiments of the present disclosure.

It should be noted that during a manufacturing process of the display panel, in order to pursue a narrower frame design, the size of a lower frame needs to be reduced. The display panel generally includes a display area and a non-display area. The non-display area can also be referred to as a frame area. The non-display area corresponding to the lower frame may be divided into a bonding area and a fan-out area disposed between the bonding area and the display area. The fan-out area is configured to arrange fan-out lines for leading wirings in the display area to the non-display area and to connect with a chip in the non-display area, so that the chip can transmit signals to the display area.

In related arts, connection wirings between signal lines in the fan-out area of the display panel and electrode layers are generally relatively complex, resulting in a frame of the panel being too wide, affecting a display effect and aesthetics. Especially when the frame is not designed compact enough, an overall size and look and feel of the display panel is affected.

In one embodiment, the display panel 1 includes a display area 1000 and a non-display area 2000 disposed on at least one side of the display area 1000. Specifically, the display panel 1 includes the display area 1000 and a bonding terminal 300 disposed on one side of the display area 1000. The bonding terminal 300 is located in the non-display area 2000. The bonding terminal 300 can be connected to an external circuit to transmit a signal input by the external circuit to the display panel 1, thereby driving the display panel to display an image. The non-display area 2000 includes a fan-out area 2100, and the fan-out area 2100 is located at one end of the non-display area 2000 close to the display area 1000.

The display panel 1 further includes a fan-out portion 211. The fan-out portion 211 is provided on one side of the substrate 11 and is located in the fan-out area 2100. The fan-out portion 211 includes a first fan-out line 123, a second fan-out line 1432, and a third fan-out line 1455 that are stacked and insulated. The first metal layer 12 includes the first fan-out line 123, the third metal layer 143 includes the second fan-out line 1432, and the second metal layer 145 includes the third fan-out line 1455. At least two of the first fan-out line 123, the second fan-out line 1432, and the third fan-out line 1455 are arranged to be overlapped with each other.

It can be understood that in this embodiment, the fan-out lines (the first fan-out line 123, the second fan-out line 1432, and the third fan-out line 1455) of different metal layers are arranged to be overlapped with each other, and a distribution the fan-out lines are optimized in the fan-out area 2100, thus allowing for providing more fan-out lines in a same space to reduce an area of the non-display area 2000. It is beneficial to improving a high resolution of the display panel 1, while meeting a design requirement of narrow frame, thereby providing a larger effective display area for the display panel 1.

At the same time, by arranging the first light-shielding part 121, the second light-shielding part 122, and the first fan-out line 123 in a same layer, by arranging the gate 1431 and the second fan-out line 1432 in a same layer, and by arranging the first electrode 1451, the second electrode 1452, the third electrode 1453, the fourth electrode 1454, and the third fan-out line 1455 in a same layer, a number of film layers of the display panel 1 is reduced and a stacking structure is optimized, which simplifies the manufacturing process of the display panel 1, effectively reduces production costs, and reduces material consumption.

Furthermore, the first fan-out line 123 and the second fan-out line 1432 are at least partially overlapped; and/or the third fan-out line 1455 and the second fan-out line 1432 are at least partially overlapped; and/or, the first fan-out line 123 and the third fan-out line 1455 are at least partially overlapped.

It should be noted that a technical proposal proposed in this embodiment is suitable for application scenarios with narrow frame of the display panel 1. In order to better illustrate the innovation of this embodiment, the solution that the first fan-out line 123 and the second fan-out line 1432 are at least partially overlapped, the third fan-out line 1455 and the second fan-out line 1432 are at least partially overlapped, and the first fan-out line 123 and the third fan-out line 1455 are at least partially overlapped is taken as an example in this embodiment for illustrating the technical proposal in this embodiment.

It can be understood that by making the first fan-out line 123 and the second fan-out line 1432 at least partially overlap, making the third fan-out line 1455 and the second fan-out line 1432 at least partially overlap, and making the first fan-out line 123 and the third fan-out line 1455 at least partially overlap, a space occupied by the fan-out lines can be effectively reduced, thereby making a layout of the fan-out lines more compact, and then improving an overall space utilization efficiency of the display panel 1.

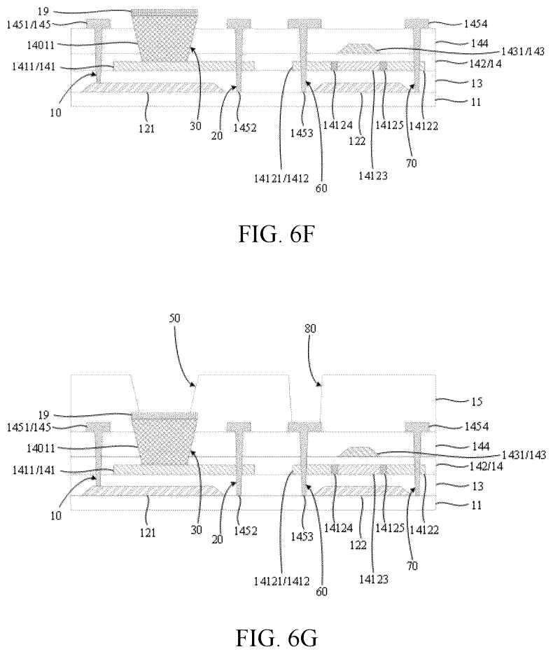

Please refer to FIG. 1, FIG. 2, FIG. 3, FIG. 4, and FIG. 5. FIG. 5 is a schematic cross-sectional diagram corresponding to C-C′ in FIG. 4 provided by embodiments of the present disclosure.

In one embodiment, the second metal layer 145 further includes a connecting part 1456. The connecting part 1456 is disposed in the fan-out area 2100. One end of the connecting part 1456 is connected to the first fan-out line 123, and another end of the connecting part 1456 is connected to the second fan-out line 1432, so that the connecting part 1456 can serve as a transition bridge for electrical connection to ensure a stable connection between the first fan-out line 123 and the second fan-out line 1432. At the same time, it avoids a complex crossing of the fan-out lines in the fan-out area 2100, reduces the space occupied by the fan-out lines, and makes the layout of the wirings of the display panel 1 more concise and compact.

Specifically, the display panel 1 is further provided with a tenth through hole 100 and an eleventh through hole 110. One end of the connecting part 1456 passes through the tenth through hole 100 to connect with the first fan-out line 123. The tenth through hole 100 penetrates the interlayer insulation layer 144, the gate insulation layer 142, and at least part of the buffer layer 13. Another end of the connecting part 1456 passes through the eleventh through hole 110 to connect with the second fan-out line 1432. The eleventh through hole 110 penetrates at least part of the interlayer insulation layer 144.

The first through hole 10, the second through hole 20, the third through hole 30, the sixth through hole 60, the seventh through hole 70, the tenth through hole 100, and the eleventh through hole 110 may be processed at one time through a photomask, which makes the manufacturing process simpler and can efficiently realize correct connections of the multiple electrodes, reducing a complexity of multiple processes.

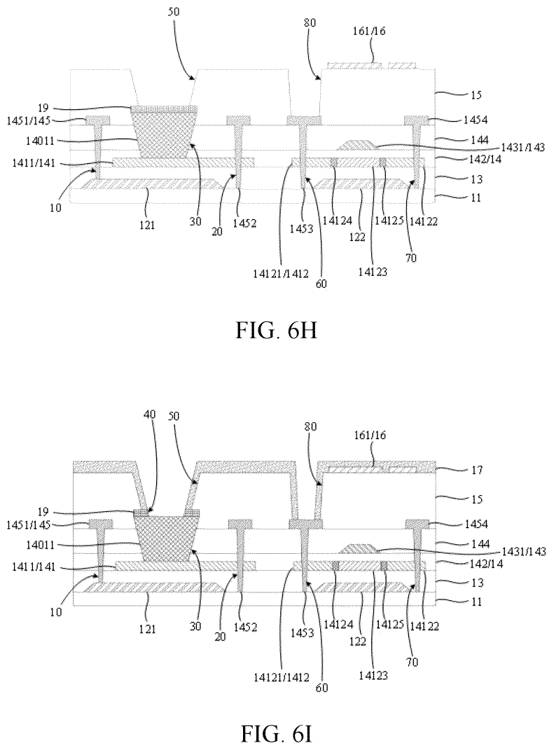

Please refer to FIG. 2 and FIG. 6A to FIG. 6I. FIG. 6A to FIG. 6I are schematic diagrams corresponding to each step of a manufacturing method of a display panel provided by embodiments of the present disclosure.

In one embodiment, a manufacturing method of the display panel 1 includes steps of S10, S20, S30, S40, S50, S60, S70, S80, S90, and S100.

As illustrated in FIG. 6A, the step S10 includes: forming a first metal layer 12 on a substrate 11, patterning the first metal layer 12 by exposure etching to form a first light-shielding part 121 and a second light-shielding part 122 spaced apart from each other.

As illustrated in FIG. 6B, the step S20 includes: sequentially forming a buffer layer 13 and first amorphous silicon (a-Si) on the first light-shielding part 121 and the second light-shielding part 122, then converting the first a-Si into polysilicon (poly-Si) by using excimer laser annealing (ELA) process, and then doping an entire surface of the poly-Si with boron ions and patterning the poly-Si by exposure etching to form a photosensitive doping part 1411 and a semi-finished semiconductor part 14120.

As illustrated in FIG. 6C, the step S30 includes: sequentially forming a gate insulation layer 142 and a third metal layer 143 on the photosensitive doping part 1411, the semi-finished semiconductor part 14120, and the buffer layer 13, pattering the third metal layer 143 to form a gate 1431, blocking part of the semi-finished semiconductor part 14120 by the gate 1431 and a photoresist, heavily doping portions of the semi-finished semiconductor part 14120 not blocked by the gate 1431 and the photoresist with phosphorus ions to form a first doped portion 14121 and a second doped portion 14122 respectively, then removing the photoresist, and lightly doping portions of the semi-finished semiconductor part 14120 not blocked by the gate 1431 with phosphorus ions to form a third doped portion 14124 and a fourth doped portion 14125 respectively, so that a portion of the semi-finished semiconductor part 14120 blocked by the gate 1431 forms a channel portion 14123.

The first doped portion 14121, the third doped portion 14124, the channel portion 14123, the fourth doped portion 14125, and the second doped portion 14122 form a semiconductor part 1412. It should be noted that, when the portions of the semi-finished semiconductor part 14120 not blocked by the gate 1431 are lightly doped with phosphorus ions to form the third doped portion 14124 and the fourth doped portion 14125 respectively, the first doped portion 14121 and the second doped portion 14122 can be blocked with a photoresist. This ensures accurate distribution of different doped portions and avoids doping concentrations that are too high or too low, resulting in device performance that does not meet requirements.

As illustrated in FIG. 6D, the step S40 includes: forming an interlayer insulation layer 144 on the gate 1431 and the gate insulation layer 142, and patterning the interlayer insulation layer 144 by using an exposure etching method to form a first sub-through hole 101, a second sub-through hole 201, a third sub-through hole 601, a fourth sub-through hole 701, and a third through hole 30 disposed apart from each other.

The first sub-through hole 101 is disposed corresponding to the first light-shielding part 121, and the first sub-through hole 101 penetrates the interlayer insulation layer 144, the gate insulation layer 142, and at least part of the buffer layer 13. The second sub-through hole 201 exposes part of the photosensitive doping part 1411, and the second sub-through hole 201 penetrates the interlayer insulation layer 144 and at least part of the gate insulation layer 142. The third sub-through hole 601 exposes part of the first doped portion 14121, and the third sub-through hole 601 penetrates the interlayer insulation layer 144 and at least part of the gate insulation layer 142. The fourth sub-through hole 701 exposes part of the second doped portion 14122, and the fourth sub-through hole 701 penetrates the interlayer insulation layer 144 and at least part of the gate insulation layer 142. The third through hole 30 exposes part of the photosensitive doping part 1411, and the third through hole 30 penetrates the interlayer insulation layer 144 and at least part of the gate insulation layer 142.

As illustrated in FIG. 6E, the step S50 includes: forming second a-Si in the third through hole 30, forming a protective layer 19 on the second a-Si, and then patterning the second a-Si by exposure etching to form a photosensitive part 14011; at the same time, patterning the interlayer insulation layer 144 to form a fifth sub-through hole 102, a sixth sub-through hole 202, a seventh sub-through hole 602, and an eighth sub-through hole 702 disposed apart from each other.

At least part of the photosensitive part 14011 is filled in the third through hole 30, and one side of the photosensitive part 14011 away from the substrate 11 protrudes from a side surface of the interlayer insulation layer 144 away from the substrate 11.

The fifth sub-through hole 102 is disposed corresponding to the first sub-through hole 101, the fifth sub-through hole 102 is communicated with the first sub-through hole 101, the fifth sub-through hole 102 exposes part of the first light-shielding part 121, and the fifth sub-through hole 102 penetrates part of the buffer layer 13. The first sub-through hole 101 and the fifth sub-through hole 102 form a first through hole 10. The six sub-through hole 202 is disposed corresponding to the second sub-through hole 201, the sixth sub-through hole 202 is communicated with the second sub-through hole 201, the sixth sub-through hole 202 exposes part of the substrate 11, and the sixth sub-through hole 202 penetrates the photosensitive doping part 1411 and the buffer layer 13. The second sub-through hole 201 and the sixth sub-through hole 202 form a second through hole 20.

The seventh sub-through hole 602 is disposed corresponding to the third sub-through hole 601, the seventh sub-through hole 602 is communicated with the third sub-through hole 601, the seventh sub-through hole 602 exposes part of the substrate 11, and the seventh sub-through hole 602 penetrates the first doped portion 14121 and the buffer layer 13. The third sub-through hole 601 and the seventh sub-through hole 602 form a sixth through hole 60. The eighth sub-through hole 702 is disposed corresponding to the fourth sub-through hole 702, the eighth sub-through hole 702 is communicated with the fourth sub-through hole 701, the eighth sub-through hole 702 exposes part of the substrate 11, and the eighth sub-through hole 702 penetrates the second doped portion 14122 and the buffer layer 13. The fourth sub-through hole 701 and the eighth sub-through hole 702 form a seventh through hole 70.

As illustrated in FIG. 6F, the step S60 includes: forming a second metal layer 145 on the interlayer insulation layer 144, and patterning the second metal layer 145 by exposure etching to form a first electrode 1451, a second electrode 1452, a third electrode 1453, and a fourth electrode 1454 disposed apart from each other. The first electrode 1451 passes through the first through hole 10 to connect with the first light-shielding part 121. One end of the second electrode 1452 passes through the second through hole 20 to connect with the photosensitive doped part 1411. The third electrode 1453 passes through the sixth through hole 60 to connect with the first doped portion 14121. The fourth electrode 1454 passes through the seventh through hole 70 to connect with the second doped portion 14122. The semiconductor part 1412, the gate insulation layer 142, the gate 1431, the interlayer insulation layer 144, the third electrode 1453, and the fourth electrode 1454 form a control unit 1402.

The first electrode 1451 is connected to the first light-shielding part 121 and applies a constant voltage (for example, a COM signal), so that the first light-shielding part 121 can maintain a constant voltage state.

As illustrated in FIG. 6G, the step S70 includes: forming a planarization layer 15 on the first electrode 1451, the second electrode 1452, the third electrode 1453, the fourth electrode 1454, and the interlayer insulation layer 144, patterning the planarization layer 15 by using an exposure and development method to form a fifth through hole 50 and an eighth through hole 80. The fifth through hole 50 exposes part of the protective layer 19, and the fifth through hole 50 penetrates part of the planarization layer 15. The eighth through hole 80 exposes part of the third electrode 1453, and the eighth through hole 80 penetrates part of the planarization layer 15.

As illustrated in FIG. 6H, the step S80 includes: forming a second transparent electrode layer 16 on the planarization layer 15, and patterning the second transparent electrode layer 16 to form a common electrode 161.

As illustrated in FIG. 6I, the step S90 includes: forming a passivation layer 17 on the planarization layer 15, the protective layer 19, and the pixel electrode 182, and patterning the planarization layer 15 by using an exposure and development method to form a fourth through hole 40 and a ninth through hole 90. The fourth through hole 40 exposes part of the photosensitive part 14011, the fourth through hole 40 and the fifth through hole 50 are communicated, and the fourth through hole 40 penetrates the passivation layer 17 and the protective layer 19. The ninth through hole 90 exposes part of the third electrode 1453, the ninth through hole 90 and the eighth through hole 80 are communicated, and the ninth through hole 90 penetrates the passivation layer 17.

As illustrated in FIG. 2, the step S100 includes: forming a first transparent electrode layer 18 on the passivation layer 17 and the photosensitive part 14011, and patterning the first transparent electrode layer 18 to form a pixel electrode 182 and a photosensitive electrode 181. The photosensitive electrode 181 passes through the fourth through hole 40 and the fifth through hole 50 to connect with the photosensitive part 14011. The pixel electrode 182 passes through the eighth through hole 80 and the ninth through hole 90 to connect with the third electrode 1453. The photosensitive electrode 181, the photosensitive part 14011, and the photosensitive doping part 1411 form a photosensitive element.

It can be understood that in this embodiment, by directly connecting the first light-shielding part 121 to a constant voltage source, it can ensure that a potential of the first light-shielding part 121 is always in a stable state. The constant voltage source provides a fixed voltage to ensure that the first light-shielding part 121 is not interfered by external signals during operation, and the potential of the first light-shielding part 121 does not float. Therefore, the potential of the first light-shielding part 121 can be effectively prevented from drifting or changing (i.e., floating). Since the light interference is effectively controlled, the photosensitive unit 1401 can sense a light signal more accurately and convert it into an electrical signal, thereby improving an efficiency and stability of the photosensitive unit 1401.

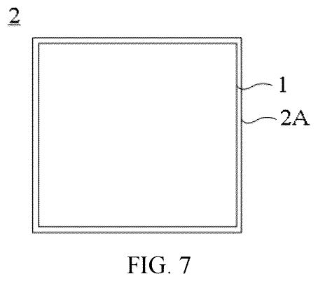

Please refer to FIG. 7. FIG. 7 is a schematic structural diagram of a display device provided by embodiments of the present disclosure.

Th embodiments also provide a display device 2. The display device 2 includes the display panel 1 described in any of the above embodiments.

It can be understood that the display panel 1 has been described in detail in the above embodiments, and the description will not be repeated here.

The display device 2 may further include a housing 2A. The housing 2A is coupled with the display panel 1 to provide support fixation and protection for the display panel 1.

In specific applications, the display device 2 may be a smart phone, a tablet computer, a mobile phone, a video phone, an e-book reader, a desktop computer, a laptop computer, a netbook, a workstation, a server, a personal digital assistant, a portable media player, an MP3 player, a mobile medical machine, a camera, a game console, a digital camera, a car navigation system, an electronic billboard, an ATM, a wearable device, or other devices with a display function.

In the above embodiments, each embodiment has its own emphasis in description. For parts that are not described in detail in a certain embodiment, please refer to the relevant descriptions of other embodiments.

The technical proposals provided by the embodiments of the present disclosure are introduced in detail above. Specific examples are used in this paper to illustrate the principles and implementation methods of the present disclosure. The description of the above embodiments is only used to help understand the technical proposals and core ideas of the present disclosure. Those of ordinary skill in the art should understand that they can still modify the technical proposals recorded in the foregoing embodiments, or make equivalent substitutions for some of the technical features; and these modifications or substitutions do not make the essence of the corresponding technical proposals in the present disclosure deviates from a scope of the technical proposals of the embodiments of the present disclosure.

1. A display panel, comprising:
a substrate;
a first metal layer disposed on the substrate and comprising a first light-shielding part; and
a photosensitive unit disposed on one side of the first light-shielding part away from the substrate, wherein the photosensitive unit comprises a photosensitive doping part, a photosensitive part, and a photosensitive electrode disposed in a stacked manner, one end of the photosensitive part is connected to the photosensitive doping part, and another end of the photosensitive part is connected to the photosensitive electrode; and
wherein an orthographic projection of the first light-shielding part on the substrate covers an orthographic projection of the photosensitive part on the substrate, and the first light-shielding part is connected to a constant voltage source.

2. The display panel according to claim 1, wherein the display panel further comprises a control unit, the control unit and the photosensitive unit are arranged apart from each other; and
the display panel further comprises a second metal layer, the second metal layer is disposed on one side of the first light-shielding part away from the substrate, the second metal layer comprises a first electrode and a second electrode arranged apart from each other, the first electrode is connected to the first light-shielding part, one end of the second electrode is connected to the photosensitive doping part, and another end of the second electrode is connected to the control unit.

3. The display panel according to claim 2, wherein the display panel further comprises a thin film transistor layer, the thin film transistor layer comprises the control unit and the photosensitive unit, and the thin film transistor layer comprises:
a semiconductor layer disposed on the substrate, wherein the semiconductor layer comprises the photosensitive doping part and a semiconductor part arranged apart from each other, and the semiconductor part comprises a first doped portion, a second doped portion, and a channel portion disposed between the first doped portion and the second doped portion; and
a third metal layer disposed on one side of the semiconductor layer away from the substrate, wherein the third metal layer comprises a gate disposed corresponding to the channel portion;
wherein the first metal layer comprises a second light-shielding part, the second light-shielding part is disposed corresponding to the semiconductor part, the second metal layer comprises a third electrode and a fourth electrode, the third electrode is connected to the first doped portion, and the fourth electrode is connected to the second doped portion.

4. The display panel according to claim 3, wherein the photosensitive doping part is arranged surrounding the second electrode.

5. The display panel according to claim 4, wherein the display panel further comprises:
a buffer layer disposed between the first metal layer the semiconductor layer;
a gate insulation layer disposed between the semiconductor layer and the third metal layer; and
an interlayer insulation layer disposed on one side of the third metal layer away from the gate insulation layer;
wherein the display panel is provided with a first through hole and a second through hole, the first electrode passes through the first through hole to connect with the first light-shielding part, and the first through hole penetrates the interlayer insulation layer, the gate insulation layer, and at least part of the buffer layer; the one end of the second electrode passes through the second through hole to connect with the photosensitive doping part, the second through hole penetrates the interlayer insulation layer, the gate insulation layer, the photosensitive doping part, and the buffer layer, and the another end of the second electrode is connected to the third electrode.

6. The display panel according to claim 5, wherein the display panel is further provided with a third through hole, at least part of the photosensitive part is filled in the third through hole, and the third through hole penetrates the interlayer insulation layer and at least part of the gate insulation layer; and
a size of one side of the photosensitive part away from the substrate is greater than a size of one side of the third through hole away from the substrate.

7. The display panel according to claim 6, wherein the display panel further comprises:
a protective layer disposed on one side of the photosensitive part away from the photosensitive doping part, wherein the protective layer is provided with a fourth through hole, and the fourth through hole penetrates the protective layer;
a planarization layer disposed on one side of the second metal layer away from the interlayer insulation layer, wherein the planarization layer is provided with a fifth through hole, the fifth through hole penetrates at least part of the planarization layer, and the fifth through hole is communicated with the fourth through hole; and
a first transparent electrode layer disposed on one side of the planarization layer away from the second metal layer, wherein the first transparent electrode layer comprises the photosensitive electrode, and the photosensitive electrode passes through the fourth through hole and the fifth through hole to connect with the photosensitive part.

8. The display panel according to claim 7, wherein the second doped portion is arranged surrounding the fourth electrode.

9. The display panel according to claim 8, wherein the display panel is further provided with a sixth through hole and a seventh through hole, the third electrode passes through the sixth through hole to connect with the first doped portion, and the sixth through hole penetrates the interlayer insulation layer, the gate insulation layer, the first doped portion, and the buffer layer; and the fourth electrode passes through the seventh through hole to connect with the second doped portion, and the seventh through hole penetrates the interlayer insulation layer, the gate insulation layer, the second doped portion, and the buffer layer.

10. The display panel according to claim 3, wherein the semiconductor part further comprises:
a third doped portion disposed between the channel portion and the first doped portion; and
a fourth doped portion disposed between the channel portion and the second doped portion;
wherein a doping concentration of the first doped portion is the same with a doping concentration of the second doped portion, a doping concentration of the third doped portion is the same with a doping concentration of the fourth doped portion, and the doping concentration of the third doped portion is less than the doping concentration of the first doped portion; and
an orthographic projection of the second light-shielding part on the substrate covers an orthographic projection of the channel portion on the substrate, an orthographic projection of the third doped portion on the substrate, and an orthographic projection of the fourth doped portion on the substrate.

11. The display panel according to claim 10, wherein the orthographic projection of the second light-shielding part on the substrate covers an orthographic projection of the third doped portion on the substrate, and the orthographic projection of the second light-shielding part on the substrate covers an orthographic projection of the fourth doped portion on the substrate.

12. The display panel according to claim 3, wherein the display panel comprises a display area and a non-display area disposed on at least one side of the display area;
the display panel further comprises a fan-out portion, the fan-out portion is disposed on one side of the substrate, the fan-out portion is located in the non-display area, and the fan-out portion comprises a first fan-out line, a second fan-out line, and a third fan-out line disposed in a stacked manner and insulated from each other; and
the first metal layer comprises the first fan-out line, the second metal layer comprises the second fan-out line, the third metal layer comprises third fan-out line, and at least two of the first fan-out line, the second fan-out line, and the third fan-out line are arranged to be overlapped with each other.

13. The display panel according to claim 12, wherein the first fan-out line and the third fan-out line are at least partially overlapped.

14. The display panel according to claim 12, wherein the second fan-out line and the third fan-out line are at least partially overlapped.

15. The display panel according to claim 12, wherein the first fan-out line and the second fan-out line are at least partially overlapped.

16. The display panel according to claim 12, wherein the second metal layer further comprises a connecting part, the connecting part is located in a fan-out area, one end of the connecting part is connected to the first fan-out line, and another end of the connecting part is connected to the second fan-out line.

17. A display device, comprising a display panel, wherein the display panel comprises:
a substrate;
a first metal layer disposed on the substrate and comprising a first light-shielding part; and
a photosensitive unit disposed on one side of the first light-shielding part away from the substrate, wherein the photosensitive unit comprises a photosensitive doping part, a photosensitive part, and a photosensitive electrode disposed in a stacked manner, one end of the photosensitive part is connected to the photosensitive doping part, and another end of the photosensitive part is connected to the photosensitive electrode; and
wherein an orthographic projection of the first light-shielding part on the substrate covers an orthographic projection of the photosensitive part on the substrate, and the first light-shielding part is connected to a constant voltage source.

18. The display device according to claim 17, wherein the display panel further comprises a control unit, the control unit and the photosensitive unit are arranged apart from each other; and
the display panel further comprises a second metal layer, the second metal layer is disposed on one side of the first light-shielding part away from the substrate, the second metal layer comprises a first electrode and a second electrode arranged apart from each other, the first electrode is connected to the first light-shielding part, one end of the second electrode is connected to the photosensitive doping part, and another end of the second electrode is connected to the control unit.

19. The display device according to claim 18, wherein the display panel further comprises a thin film transistor layer, the thin film transistor layer comprises the control unit and the photosensitive unit, and the thin film transistor layer comprises:
a semiconductor layer disposed on the substrate, wherein the semiconductor layer comprises the photosensitive doping part and a semiconductor part arranged apart from each other, and the semiconductor part comprises a first doped portion, a second doped portion, and a channel portion disposed between the first doped portion and the second doped portion; and
a third metal layer disposed on one side of the semiconductor layer away from the substrate, wherein the third metal layer comprises a gate disposed corresponding to the channel portion;
wherein the first metal layer comprises a second light-shielding part, the second light-shielding part is disposed corresponding to the semiconductor part, the second metal layer comprises a third electrode and a fourth electrode, the third electrode is connected to the first doped portion, and the fourth electrode is connected to the second doped portion.

20. The display device according to claim 19, wherein the photosensitive doping part is arranged surrounding the second electrode.
